(19) United States
(12) Patent Application Publication
(10) Pub. No.: US 2007/0120243 A1
(43) Pub. Date: May 31, 2007

(54) Assembly jig and manufacturing method of multilayer semiconductor device

(75) Inventors: Yoshiyuki Yanagisawa, Kanagawa (JP); Toshiharu Yanagida, Tokyo (JP); Masashi Enda, Kanagawa (JP); Yuichi Takai, Tokyo (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(73) Assignee: SONY CORPORATION

(21) Appl. No.: 11/646,158

(22) Filed: Dec. 27, 2006

Related U.S. Application Data
(63) Continuation of application No. 09/876,290, filed on Jun. 7, 2001.

(30) Foreign Application Priority Data
Jun. 7, 2000 (JP) P2000-171059

(51) Int. Cl. H01L 23/02

(52) U.S. Cl. 257/686

(57) ABSTRACT

There are provided a base member 14, a position restriction mechanism 15, a height restriction mechanism 17, an evenness holding mechanism, and an alignment mechanism 20, 22. A plurality of semiconductor modules is serially layered on the base member. Each semiconductor module comprises a semiconductor chip 7 mounted on a printed-wiring board 6 and a bump 13 formed on an interlayer connection land 8. The position restriction mechanism 15 restricts respective positions of the semiconductor modules 2 to be layered on the base member 14. The height restriction mechanism 17 restricts the height of the entire layered semiconductor module unit 4 layered on the base member 14. The evenness holding mechanism maintains evenness of the semiconductor module 2. The alignment mechanism 20, 22 aligns a mother substrate 5 on which a multilayer semiconductor module unit 4 is mounted.

### BACKGROUND OF THE INVENTION

1. Technical Field

The present invention relates to an assembly jig and a manufacturing method of a multilayer semiconductor device. More specifically, the present invention relates to an assembly jig and a method appropriately used for manufacturing a multilayer semiconductor device comprising semiconductor chips mounted on a thin printed-wiring board and many layered semiconductor modules each having bumps formed on many interlayer connection lands.

2. Prior Art

As a semiconductor device, a multilayer semiconductor device 100 in FIG. 1 is provided for improving a packaging density for semiconductor chips. As shown in FIG. 1 (c), the multilayer semiconductor device 100 comprises many semiconductor modules 101 (101a to 101d) layered on a mother substrate 102. As shown in FIG. 1 (a), each semiconductor module 101 comprises a semiconductor chip 103 mounted on a flexible interposer (thin printed-wiring board) 104 through the use of an anisotropic conductive material, solder 105, and the like. The semiconductor chip 103 is thinned by means of polishing and the like.

There are formed terminal conductors and appropriate circuit conductors (not shown) for connecting surface electrodes in a region 104b for mounting the semiconductor chip 103 on a first principal plane 104a of the printed-wiring board 104. Around the semiconductor chip mounting region 104b of the printed-wiring board 104, there is formed a plurality of interlayer connection lands 106 and 107 on a first principal plane 104a and a second principal plane 104c, respectively. The interlayer connection lands 106 and 107 are connected to appropriate through-holes whose details are omitted. A bump 108 comprising a solder ball or the like is provided on an interlayer connection land 106 on the first principal plane 104a of the printed-wiring board 104.

The semiconductor module 101 is subject to processes such as mounting the semiconductor chip 103 on the semiconductor chip mounting region 104b of the printed-wiring board 104, applying flux or soldering paste to the interlayer connection land 106 on the printed-wiring board 104, and providing the bump 108 held by adhesion of the flux and the like on the interlayer connection land 106. When the semiconductor module 101 is supplied to a reflow furnace, the bump 108 is melted and is fixed onto the interlayer connection land 106. The semiconductor module 101 is subject to a per-piece inspection by performing burn-in, a function test, and the like, and then is supplied to the next process.

The semiconductor module 101 is subject to a process of applying flux or soldering paste to the bump 108 on the first principal plane 104a and the interlayer connection land 107 on the second principal plane 104c. With the second principal plane 104c as a mounting surface, the semiconductor module 101, as shown in FIG. 1 (b), is layered on a base substrate 109 formed of a ceramic material and the like. A chip mounter (not shown) is used to layer semiconductor modules 101 one by one.

A first-layer semiconductor module 101a is mounted and held on the base substrate 109 by means of an adhesive strength of soldering paste applied to the interlayer connection land 107. A second-layer semiconductor module 101b is mounted and held on the first principal plane 104a of the first-layer semiconductor module 101a by means of an adhesive strength of soldering paste applied to the bump 108 of the first-layer semiconductor module 101a and to the interlayer connection land 107. Likewise, the respective semiconductor module 101a to 101d are layered in order. This layering state is maintained by the soldering paste.

When a layered unit is supplied to the reflow furnace, the bump 108 is melted and is fixed onto the other interlayer connection land 107. Consequently, a layered semiconductor module unit 110 as shown in FIG. 1 (b) is configured. In the layered semiconductor module unit 110, the interlayer connection lands 106 and 107 are connected through the bump 108 to establish connection between the semiconductor modules 101a to 101d. As shown in FIG. 1 (c), the layered semiconductor module unit 110 is reversed by the chip mounter and is mounted on the mother substrate 102 with a fourth-layer semiconductor module 101d as a first layer.

A layered unit of the semiconductor module 101 and the mother substrate 102 is supplied to the reflow furnace. As regards the layered unit of the semiconductor module 101 and the mother substrate 102, the bump 108 on the fourth-layer semiconductor module 101d in the layered semiconductor module unit 110 is melted and is fixed to a connection land 111 of the mother substrate 102. This provides an entire interlayer connection and to complete the multilayer semiconductor device 100.

In a conventional manufacturing process for the multilayer semiconductor device 100, an adhesive strength of the soldering paste maintains a layered state of the semiconductor modules 101 on the base substrate 109 until reflow heat treatment is applied. Accordingly, when a chip mounter is operated during the conventional manufacturing process, for example, positional displacement occurs among many layered semiconductor modules 101, causing a connection failure between layers. It is possible to solve this problem by using a special chip mounter having a positional displacement restriction mechanism. However, such a special-purpose apparatus increases machinery costs and decreases productivity due to a process change a setup process, and the like.

According to the conventional manufacturing process, many semiconductor modules 101 are layered on the base substrate 109 and reflow heat treatment is applied. In such a situation, a connection failure occurred between layers due to a warp on the thin printed-wiring board 104 or variability of a diameter of the bump 108. In the conventional manufacturing process, a similar problem also occurs when the layered semiconductor module unit 110 is mounted on the mother substrate 102 and reflow heat treatment is applied.

It is also important that the multilayer semiconductor device 100 be requested to provide a high-precision thin characteristic on the order of 0.1 mm. The conventional manufacturing process supplies the highly precisely fabricated printed-wiring board 104 and mother substrate 102. A high-precision bump formation apparatus is used for forming the bump 108. However, the conventional manufacturing process provides no measures for restricting the entire height during a process. Consequently, the conventional manufacturing process caused the problem that variability of the entire height increases as the number of layers increases, resulting in large variability in the height of the multilayer semiconductor device 100. This is also due to a warp on the printed-wiring board 104 or variability of a diameter of the bump 108 during the above-mentioned reflow heat treatment.

Since the multilayer semiconductor device 100 employs different interlayer connections between respective layers of the semiconductor modules 101, the bumps 108 are not arranged and formed evenly on the printed-wiring board 104. Accordingly, the manufacturing process for the multilayer-semiconductor device 100 increases a warp on the printed-wiring board 104 of each semiconductor module 101 making the above-mentioned problem more remarkable. The multilayer semiconductor device 100 also presented the problem that the printed-wiring board 104 is bent to concentrate a stress on a connection point of the bump 108, causing peeling or a contact failure.

### BRIEF SUMMARY OF THE INVENTION

It is therefore an object of the present invention to provide an assembly jig and a manufacturing method of a multilayer semiconductor device which establishes a secure interlayer connection, maintaining the height precision and reliability, and improves the yield and productivity.

For achieving the above-mentioned objects, a multilayer semiconductor device assembly jig according to the present invention comprises a base member for serially layering a plurality of semiconductor modules each including a semiconductor chip mounted on a thin printed-wiring board and a bump on each of a plurality of interlayer connection lands; a position restriction mechanism for layering the semiconductor modules with mutual positions restricted on the base member; a height restriction mechanism for restricting an entire height of the semiconductor module group layered on the base member; an evenness holding mechanism for maintaining evenness of a top-layer semiconductor module; and an alignment mechanism for providing alignment with reference to a mother substrate where a layered semiconductor module unit is mounted.

An assembly jig for the thus configured multilayer semiconductor device according to the present invention allows many semiconductor modules to be layered on a base member with mutual positions restricted by the position restriction mechanism and the entire height specified by the height restriction mechanism. When the multilayer semiconductor device's assembly jig is transported into the reflow furnace, reflow heating is applied to each semiconductor module. Each bump between interlayer connection lands is melted and hardened for interlayer connection between semiconductor modules. The multilayer semiconductor device's assembly jig mutually positions respective semiconductor modules for securing interlayer connection and maintaining a specified height. For manufacturing a layered semiconductor module unit, the evenness holding mechanism maintains evenness of a top-layer semiconductor module which functions as a junction semiconductor module with the mother substrate.

The multilayer semiconductor device's assembly jig, when inverted, is aligned to and combined with the mother substrate via an alignment mechanism, aligning and mounting the layered semiconductor module unit on this mother substrate. The multilayer semiconductor device's assembly jig holds the layered semiconductor module unit by means of the position restriction mechanism and the height restriction mechanism. With this state maintained, the assembly jig is transported into the reflow furnace together with the mother substrate and is subject to reflow heating. The multilayer semiconductor device's assembly jig manufactures a multilayer semiconductor device in such a manner that a bump on the first-layer semiconductor module is melted and is hardened between this module and an adjacent interlayer connection land for providing an interlayer connection with the mother substrate. The multilayer semiconductor device's assembly jig is removed from the mother substrate. The multilayer semiconductor device's assembly jig makes it possible to effectively manufacture a multilayer semiconductor device by providing a highly precise interlayer connection among the semiconductor modules and the mother substrate and maintaining a precision height.

A multilayer semiconductor device manufacturing method according to the present invention for achieving the above-mentioned objects uses an assembly jig having a base member for serially layering a plurality of semiconductor modules each including a semiconductor chip mounted on a printed-wiring board and a bump on an interlayer connection lands, a position restriction mechanism for layering the semiconductor modules with respective positions restricted on the base member, and a height restriction mechanism for restricting an entire height of the semiconductor module group layered on the base member. The multilayer semiconductor device manufacturing method comprises the steps of: serially layering the specified number of the semiconductor modules on the base member with respective positions restricted by the position restriction mechanism and placing layered modules in the assembly jig with an entire height restricted by the height restriction mechanism; and supplying the assembly jig into a reflow furnace, applying reflow heating to melt the bump for interlayer connection among the semiconductor modules, and forming a layered semiconductor module unit.

The multilayer semiconductor device manufacturing method uses the above-mentioned assembly jig having the alignment mechanism for alignment with the mother substrate to be mounted. After a layered semiconductor module unit is formed, the assembly jig is inverted and is aligned to a mother substrate via the alignment mechanism. This manufacturing method comprises the steps of combining the layered semiconductor module unit with a topmost semiconductor module as a junction semiconductor module having evenness maintained by an evenness holding mechanism; supplying an assembly of the assembly jig and the mother substrate into a reflow furnace and applying reflow heating for interlayer connection between a first-layer semiconductor module in the layered semiconductor module unit and the mother substrate; and removing the assembly jig from the mother substrate.

According to the manufacturing method comprising the above-mentioned processes for the multilayer semiconductor device, the use of the above-mentioned assembly jig allows the position restriction mechanism to mutually align respective semiconductor modules. In addition, the height restriction mechanism precisely keeps the entire height to a specified value for manufacturing a layered semiconductor module unit. The manufacturing method for multilayer semiconductor devices according to the present invention uses a simple apparatus to suppress effects of a printed-wiring board warp, bump size variability, and the like, and to secure an interlayer connection between the semiconductor modules. Consequently, it is possible to manufacture a highly reliable multilayer semiconductor device with low costs and high productivity.

As mentioned above in detail, the multilayer semiconductor device's assembly jig according to the present invention uses the position restriction mechanism to mutually align many semiconductor modules layered on a base member. The height restriction mechanism restricts the entire height. Further, the evenness holding mechanism maintains evenness. With this state, the reflow heating is applied for interlayer connection. This suppresses effects of a printed-wiring board warp, bump diameter variability, and the like for precise connection between the layers. The entire height is also maintained precisely, making it possible to effectively manufacturing a highly reliable multilayer semiconductor device. The multilayer semiconductor device's assembly jig eliminates the need for a costly chip mounter having an alignment mechanism and the like, provides easy operations, and decreases costs by streamlining inspection processes.

The manufacturing method for multilayer semiconductor devices according to the present invention regulates mutual positions of many semiconductor modules and specifies the entire height. Further, the assembly jig is used for maintaining evenness and performs reflow heating for providing an interlayer connection. Consequently, the simple apparatus suppresses effects of a printed-wiring board warp, bump size variability, and the like for securing an interlayer connection between the semiconductor modules. Therefore, it is possible to manufacture a highly reliable multilayer semiconductor device with low costs and high productivity.

### BRIEF DESCRIPTION OF THE SEVERAL VIEWS OF THE DRAWING

FIG. 1 illustrates a conventional process of manufacturing a multilayer semiconductor device;

FIG. 2 illustrates a process of manufacturing a multilayer semiconductor device according to the present invention;

FIG. 3 is a longitudinal sectional view of an assembly jig used for the manufacturing process;

FIG. 4 illustrates a process of mounting a layered semiconductor module unit on a mother substrate by using the assembly jig;

FIG. 5 is a top view of another assembly jig, comprising a longitudinal sectional view (a) and a top view (b) with a cover removed; and

FIG. 6 is a longitudinal sectional view of another assembly jig.

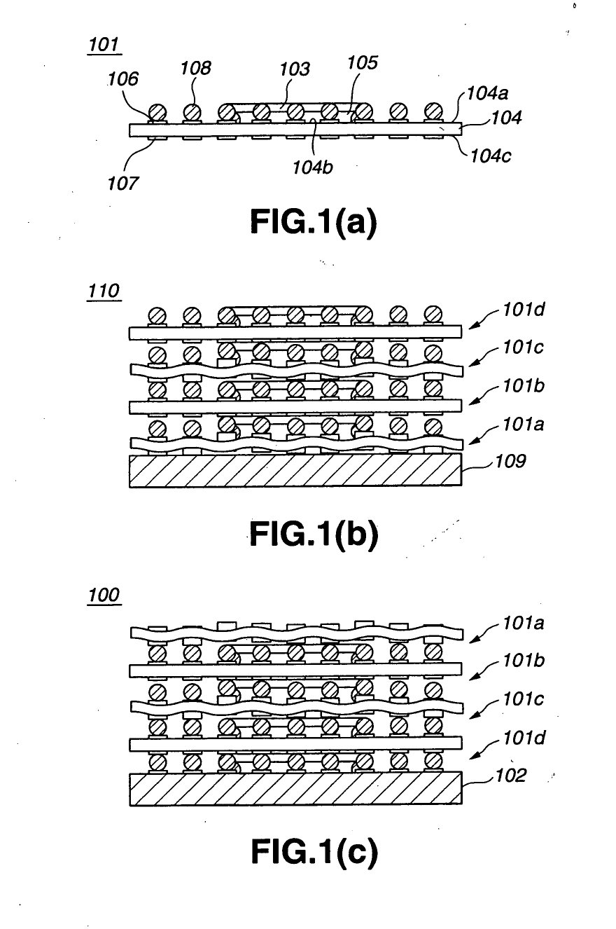

### DETAILED DESCRIPTION OF THE INVENTION

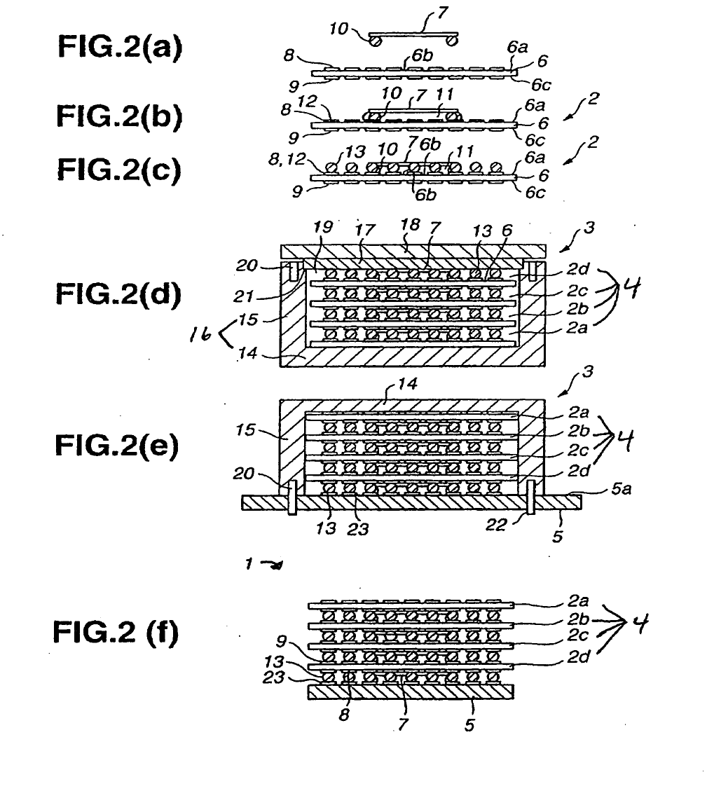

Embodiments of the present invention will be described in further detail with reference to the accompanying drawings. Manufacturing processes for the multilayer semiconductor device 1 according to the embodiment are almost the same as those for the above-mentioned conventional multilayer semiconductor device 100. As shown in FIG. 2, the multilayer semiconductor device 1 in FIG. 2 (f) is manufactured through the following processes. Namely, a semiconductor module 2 is manufactured. A layered semiconductor module unit 4 is manufactured by layering many semiconductor modules 2 (2a to 2d) through the use of a assembly jig 3. Finally, the layered semiconductor module unit 4 is mounted on a mother substrate 5 through the use of a assembly jig 3.

The manufacturing processes for the semiconductor module 2 include a process of mounting a semiconductor chip 7 on a printed-wiring board 6 as a first process. As regards the printed-wiring board 6, a photographic technique or the like is used to form a proper circuit conductor (details omitted) on a thin substrate comprising a copper foil or the like attached to an insulation film as a base material. As shown in FIG. 2 (a), the printed-wiring board 6 has a semiconductor chip mounting region 6b formed at the center of a first principal plane 6a. Appropriate terminal lands are formed in the semiconductor chip mounting region 6b. Many first interlayer connection lands 8 are formed around the semiconductor chip mounting region 6b. A second interlayer connection land 9 is formed corresponding to the first interlayer connection land 8 on the second principal plane 6b of the printed-wiring board 6.

The printed-wiring board 6 is not only designed to mount the semiconductor chip 7 directly on the first principal plane 6a. It may be also preferable to cut out a hole corresponding to the semiconductor chip 7 in the semiconductor chip mounting region 6b and form terminal lands-around this hole. Further the printed-wiring board 6 may be formed like a long tape for serially mounting the semiconductor chip 7 in each region to be cut properly. In this case, perforations and the like are formed on both sides thereof for continuous transportation.

On the printed-wiring board 6, a through-hole (details omitted) is used for connection between the interlayer connection lands 8 and 9 corresponding to each other on first and second surfaces. The printed-wiring board 6 uses common arrangement of the interlayer connection lands 8 and 9 for all the semiconductor modules 2. Accordingly, the printed-wiring board 6 configures a dummy land, say, by removing connection between a circuit conductor and part of the interlayer connection lands 8 and 9.

The semiconductor chip 7 is used as, say, an integrated circuit element, a memory chip, and the like and is thinned by applying a process such as polishing to packaging resin. A proper surface electrode (details omitted) is formed on the surface of the semiconductor chip 7. As shown in FIG. 2 (a), an anisotropic conductive material is applied to these electrodes or a bump 10 is formed thereon.

As shown in FIG. 2 (b), the semiconductor module 2 is arranged in such a way that the semiconductor chip 7 is mounted according to bare chip mounting on the semiconductor chip mounting region 6b of the printed-wiring board 6. On the semiconductor module 2, underfill 11 is filled between the printed-wiring board 6 and the semiconductor chip 7 to reinforce and fix the semiconductor chip 7 for mounting it on the semiconductor chip mounting region 6b. Of course, it may be preferable to arrange the semiconductor module 2 in such a way that, say, wire bonding is used for connection between each surface electrode and the terminal land to mount the semiconductor chip 7 on the printed-wiring board 6.

During the manufacturing process for the semiconductor module 2, flux or soldering paste 12 is applied to the first interlayer connection land 8 of the printed-wiring board 6 as shown in FIG. 2 (b). The soldering paste 12 is applied to all the interlayer connection lands 8 including dummy lands. In the manufacturing processes for the semiconductor module 2, a bump 13 comprising a solder ball or the like is provided from a bump feeder on all the interlayer connection lands 8 as shown in FIG. 2 (c). The bump 13 is held on the first interlayer connection land 8 by means of adhesive strength of the soldering paste 12. The semiconductor module 2 is subject to an inspection by performing burn-in, a function test, and the like.

As mentioned above, the semiconductor module 2 uses the thin printed-wiring board 6 as a base material. Since the semiconductor module 2 is almost evenly provided with the interlayer connection land 8, dummy lands, and the bump 13, the structure is characterized by improved mechanical rigidity and an adjusted weight balance. Accordingly, the semiconductor module 2 is almost free from deformation and the like during subsequent processes.

After the above-mentioned inspection, the semiconductor module 2 is transferred to a manufacturing process using the assembly jig 3 for the layered semiconductor module unit 4. In the manufacturing process for the layered semiconductor module unit 4, the assembly jig 3 is used to align four semiconductor modules 2a to 2d to each other. Further, the height restriction is performed for layering these modules to assemble the layered semiconductor module unit 4. After the flux or soldering paste is applied to the surface of the second interlayer connection land 9 on the second principal plane 2c and the surface of the bump 13, each semiconductor module 2 is placed in the assembly jig 3.

As shown in FIG. 2 (d), the semiconductor modules 2 are placed in the assembly jig 3 serially from the second principal plane 4c side. The semiconductor modules 2 are aligned to each other as will be described later. The bump 13 formed on the first principal plane 4a (lower-layer side) is correspondingly positioned to the second interlayer connection land 9 formed on the second principal plane 4c (upper-layer side). The semiconductor modules 2 are joined to each other by means of adhesive strength of the soldering paste.

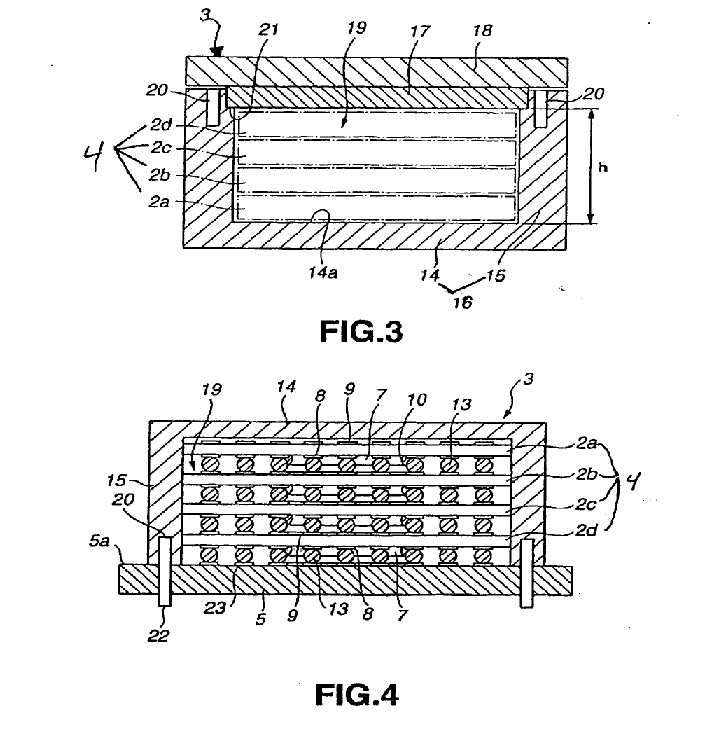

As shown in FIGS. 2 (d) and 3, the assembly jig 3 comprises a box-shaped main body 16 further comprising a base 14 and a body 15, a height restriction member 17, and a cover 18. The assembly jig 3 contains four semiconductor modules 2 in a layered state. In the assembly jig 3, an inner face 14a of the base 14 is formed with relatively high precision. The four semiconductor modules 2 are serially layered to assemble the layered semiconductor module unit 4 by using the inner face 14a as a reference plane.

The assembly jig 3 includes an internal space of the body 15 constituting a layering space 19 for the semiconductor module 2. The sectional dimension thereof is formed almost equally to the outside dimension of the semiconductor module 2. The assembly jig 3 is designed for alignment of respective modules in such a way that an inner surface of the body 15 restricts an outer periphery of the semiconductor modules 2 placed in the layering space 19. Accordingly, the assembly jig 3 constitutes a position restriction mechanism in which the body 15 restricts respective positions of the semiconductor modules 2 for layering.

The assembly jig 3 has a positioning hole 20 formed in a height direction at the top end of the body 15. The positioning holes 20 are formed at the top ends of at least three sides and constitute a positioning mechanism for combining the assembly jig 3 with the mother substrate 5 as will be described later. The assembly jig 3 has a support stage 21 formed on the inner surface of the body 15 by maintaining a specified height from the inner face 14a of the base 14. The support stage 21 is recessed on the inner surface of the body 15 in such a way that an opening dimension of the layering space 19 is slightly increased. The support stage 21 is formed equally to a layered dimension of four semiconductor modules 2a to 2d with height “h”.

When the four semiconductor modules 2a to 2d are placed in the layering space 19, the height restriction member 17 is assembled on the top of the assembly jig 3. The height restriction member 17 has an outside dimension slightly larger than the sectional dimension of the body 15 and is formed almost equally to the opening dimension corresponding to the support stage 21. A bottom face 17a thereof is supported by the support stage 21. The height restriction member 17 has its bottom face 17a formed with relatively high flatness accuracy. With the state assembled to the body 15, the bottom face 17a and the inner face 14a of the base 14 restrict the height of the layering space 19 to “h”.

The layered semiconductor module unit 4 comprises the semiconductor modules 2a to 2d which are prone to height variabilities. These variabilities result from variabilities of the thickness of the printed-wiring board 6, the diameter of the bump 13, the thickness of the soldering paste 12, and the like for each of these modules. The assembly jig 3 uses the height restriction member 17 to press the topmost semiconductor module 2d for restricting the height of the layered semiconductor module unit 4 to “h”. The height restriction member 17 is held by a cover 18 provided on the assembly jig 3.

With this state maintained, the assembly jig 3 is supplied to the reflow furnace for performing interlayer connection among the semiconductor modules 2a to 2d. When the reflow heating is applied to the semiconductor modules 2a to 2d, the bump 13 on each layer is melted and is fixed to the corresponding second interlayer connection land 9 on the upper-layer side. This performs the interlayer connection to form the layered semiconductor module unit 4.

A heat load due to the reflow heating causes a warp on each printed-wiring board 6 in the layered semiconductor module unit 4. As mentioned above, the assembly jig 3 restricts the entire height, suppressing deformation due to this warp. The layered semiconductor module unit 4 is characterized by suppressing positional errors among the semiconductor modules 2a to 2d and by precisely maintaining the entire height to the dimension “h”. There is provided a secure connection state between the first interlayer connection land 8 and the facing second interlayer connection land 9. The layered semiconductor module unit 4 also maintains evenness of the semiconductor modules 2a to 2d.

After the assembly jig 3 is taken out of the reflow furnace and is cooled as specified, it is supplied to a process of mounting the layered semiconductor module unit 4 on the mother substrate 5. The height restriction member 17 and the cover 18 are removed from the assembly jig 3. Then, the assembly jig 3 is reversed by a handling apparatus and is placed on the mother substrate 5. In the semiconductor module unit 4, the top-layer semiconductor module 2d is used as a junction module for the mother substrate 5.

The assembly jig 3 is manipulated by a proper holding mechanism so that the layered semiconductor module unit 4 is retained in the layering space 19. As shown in FIGS. 2 (e) and 4, the assembly jig 3 is positioned to the mother substrate 5 and is combined therewith in such a way that a positioning pin 22 provided in a marginal region 5a of the mother substrate 5 fits in the positioning hole 20. This combination state in the assembly jig 3 is maintained by a mechanical clamper, an adhesive tape, or a weight (details omitted).

The mother substrate 5 comprises a printed-wiring board having mechanical rigidity and a thickness larger than that of printed-wiring board 6 for the semiconductor module 2 and constitutes a base for the multilayer semiconductor device 1. The mother substrate 5 constitutes an external connection member in which a proper connection terminal or circuit conductor (details omitted) is formed. The mother substrate 5 includes an interlayer connection land 23 formed corresponding to the second interlayer connection land 9 for the semiconductor module 2. When the layered semiconductor module unit 4 is mounted soldering paste or the like is applied onto the interlayer connection land 23 of the mother substrate 5.

An assembly of the assembly jig 3 and the mother substrate 5 is supplied to the reflow furnace for performing an interlayer connection between the mother substrate 5 and the semiconductor module 2d. Namely, when the reflow heating is applied, the bump 13 is melted and hardened between the corresponding interlayer connection land 23 and the first interlayer connection land 8, performing an interlayer connection between the mother substrate 5 and the semiconductor module 2d. After the assembly jig 3 is taken out of the reflow furnace and is cooled as specified, the assembly jig 3 is removed from the mother substrate 5. A dicer or the like is used for cutting off the marginal region 5a from the mother substrate 5 to form the multilayer semiconductor device 1 with the layered semiconductor module unit 4 mounted thereon.

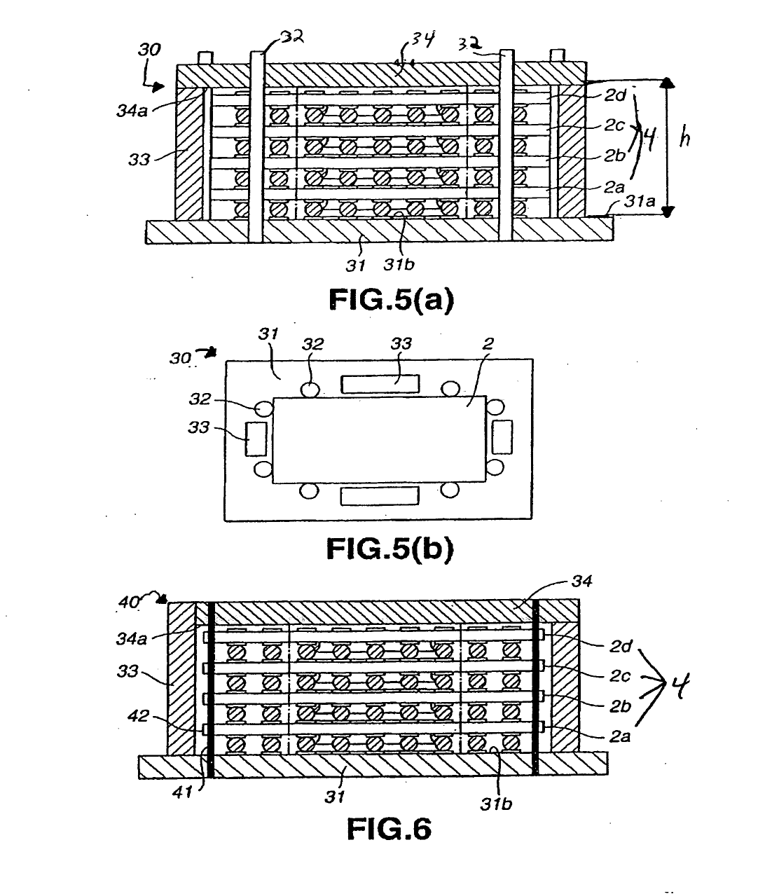

The assembly jig 3 has the main body 16 comprising the box-shaped body 15 formed integrally to the base 14 as mentioned above, but is not limited to such a structure. An assembly jig 30 in FIG. 5 comprises a base plate 31, a plurality of height restriction spacers 33, and a cover 34. The base plate 31 has an outside dimension larger than that of the semiconductor module 2. A principal plane 31a is formed with relatively high flatness accuracy. The base plate 31 has a layering region 31b for the semiconductor modules 2 at the center of the principal plane 31a. The principal plane 31a is used as a reference plane for serially layering the semiconductor modules 2.

Positioning guide pins 32 are provided around the layering region 31b of the base plate 31. As shown in FIG. 5, a pair of positioning guide pins 32 is provided for corresponding sides of the printed-wiring board 6 so that the pins touch near both sides. The positioning guide pins 32 restrict an outer periphery of the printed-wiring board 6 of the semiconductor module 21 or aligning each semiconductor module 2. When the printed-wiring board 6 is small, for example, it may be preferable to provide one positioning guide pin 32 for each side. It may be also preferable to arrange the positioning guide pins so that they touch at least three sides at different positions.

On the base plate 31, a height restriction spacer 33 is provided between a pair of positioning guide pins 32. As shown in FIG. 5 (b), each height restriction spacer 33 has a rectangular section having a longer side corresponding to each side of the printed-wiring board 6. Height “h” from the base plate 31 to the top of each spacer equals the height of the four layered semiconductor modules 2a to 2d. The cover 34 has an outside dimension slightly larger than that of the semiconductor module 2. A bottom face 34a thereof is formed with relatively high flatness accuracy.

In the assembly jig 30, four semiconductor modules 2a to 2d are serially layered on the base plate 31. The assembly jig 30 aligns the semiconductor modules 2a to 2d to each other by restricting outer layers using each positioning guide pin 32. After the semiconductor modules 2 are layered, the cover 34 is mounted on the height restriction spacer 33 of the assembly jig 30. The assembly jig 30 restricts the entire height and maintains evenness in such a manner that the cover 34 presses the semiconductor modules 2.

As is the case with the above-mentioned assembly jig 3, the assembly jig 30 is supplied to the reflow furnace. The assembly jig 30 then is subject to processes of performing interlayer connection among semiconductor modules 2 and mounting them on the mother substrates. Thereafter, the assembly jig 30 is removed from the mother substrate 5 to manufacture the multilayer semiconductor device 1. As shown in FIG. 5 (a), the assembly jig 30 has the positioning guide pins 32 each of which is longer than the height restriction spacer 33. Therefore, the positioning guide pin 32 is also used for alignment with the mother substrate 5. Of course, all the positioning guide pins 32 need not be longer than the height restriction spacers 33.

The assembly jig 30 uses the positioning guide pins 32 to partially regulate the outer periphery of the printed-wiring board 6. This structure eases an operation of layering the semiconductor modules 2 on the base plate 31. The assembly jig 30 also allows easy maintenance for cleaning of members and the like.

An assembly jig 40 in FIG. 6 has almost the same basic structure as that of the assembly jig 30. The assembly jig 40 is characterized in that a plurality of positioning guide pins 41 pierces each semiconductor module 2 for aligning these modules to each other. Namely, a positioning hole 42 is formed on the outer periphery of the printed-wiring board 6 for the semiconductor module 2. These modules are layered on the base plate 31 of the assembly jig 40. The positioning holes 42 are formed as through-holes, say, at four corners of the printed-wiring board 6 where circuit conductors or the like are not formed. Each positioning guide pin 41 is provided on the base plate 31 corresponding to the positioning hole 42.

According to this assembly jig 40, the semiconductor modules 2 are serially layered so that each positioning guide pin 41 pierces the corresponding positioning hole 42. Hence, the assembly jig 40 highly precisely aligns the semiconductor modules 2 and securely maintains this alignment state. When the assembly jig 40 and the semiconductor module 2 are relatively small, it may be preferable to form the positioning guide pins 41 and the positioning holes 42 fitting to each other at three different positions.

1-7. (canceled)

8. A multilayer semiconductor device manufacturing method using an assembly jig for mutually restricting positions of a plurality of semiconductor modules each including a semiconductor chip mounted on a thin printed-wiring board and a bump on each of a plurality of interlayer connection lands through the use of a position restriction mechanism, layering said modules with an entire height restricted through the use of a height restriction mechanism, and maintaining evenness of a top-layer semiconductor module through the use of a an evenness holding mechanism, comprising the steps of:
serially layering the plurality of semiconductor modules on said base member with their respective positions restricted by said position restriction mechanism of said assembly jig and their entire height restricted by said height restriction mechanism of said assembly jig;
supplying said assembly jig into a reflow furnace, applying reflow heating to melt said each bump for interlayer connection among said semiconductor modules, and forming a layered semiconductor module unit while restricting the vertical and horizontal deformation of the semiconductor module unit via said height and position restriction mechanisms; and
mounting said layered semiconductor module unit on a mother substrate by using a top-layer semiconductor module as a junction module with evenness maintained by said evenness holding mechanism.

9. The multilayer semiconductor device manufacturing method according to claim 8, further providing said assembly jig with an alignment mechanism for aligning said layered semiconductor module unit with said mother substrate for mounting, comprising the steps of:
positioning and combining said assembly jig, inverted after forming layered semiconductor module unit, with said mother substrate via said alignment mechanism;
supplying an assembly of said assembly jig and said mother substrate into a reflow furnace and applying reflow heating for interlayer connection between a first-layer semiconductor module in said layered semiconductor module unit and said mother substrate; and
removing said assembly jig from said mother substrate.

10. The multilayer semiconductor device manufacturing method according to claim 8 using said printed-wiring board having interlayer connection lands and dummy lands corresponding to interlayer connection lands on all printed-wiring boards for respective layers, comprising the step of:
forming a bump on each of connection lands and dummy lands of said printed-wiring board for each semiconductor module.

11. The multilayer semiconductor device manufacturing method according to claim 8, further wherein said jig comprises a semiconductor alignment mechanism and wherein, during said layering step, the alignment mechanism causes each semiconductor module to be aligned with an adjacent semiconductor module.

12. The multilayer semiconductor device manufacturing method according to claim 9, wherein said alignment mechanism comprises positioning pins which, during the layering step, pierce through holes formed in each semiconductor module at respective positions.

13. A method of forming a multilayer semiconductor device using an assembly jig for mutually restricting positions of a plurality of semiconductor modules, each including at least a thin printed-wiring board and a bump on each of a plurality of interlayer connection lands, comprising the steps of:
serially layering the plurality of said semiconductor modules on a base member with respective positions restricted by a position restriction mechanism;
supplying said assembly jig into a reflow furnace, applying reflow heating to melt each bump for interlayer connection and thereby forming a layered semiconductor module unit; and
mounting said layered semiconductor module unit on a mother substrate.

14. The multilayer semiconductor device manufacturing method according to claim 13, further providing said assembly jig with an alignment mechanism for aligning said layered semiconductor module unit with said mother substrate for mounting, comprising the steps of:
positioning and combining said assembly jig, inverted after forming layered semiconductor module unit, with said mother substrate via said alignment mechanism;
supplying an assembly of said assembly jig and said mother substrate into a reflow furnace and applying reflow heating for interlayer connection between a first-layer semiconductor module in said layered semiconductor module unit and said mother substrate; and
removing said assembly jig from said mother substrate.

15. The multilayer semiconductor device manufacturing method according to claim 13, wherein said assembly jig further comprises a height restriction mechanism which restricts a total height of the layered semiconductor module unit during reflow.

16. The multilayer semiconductor device manufacturing method according to claim 13 using said printed-wiring board having interlayer connection lands and dummy lands corresponding to interlayer connection lands on all printed-wiring boards for respective layers, comprising the step of:
forming a bump on each of connection lands and dummy lands of said printed-wiring board for each semiconductor module.

17. The multilayer semiconductor device manufacturing method according to claim 13, further wherein said jig comprises a semiconductor alignment mechanism and wherein, during said layering step, the alignment mechanism causes each semiconductor module to be aligned with an adjacent semiconductor module.

18. The multilayer semiconductor device manufacturing method according to claim 17, wherein said alignment mechanism comprises positioning pins which, during the layering step, pierce through holes formed in each semiconductor module at respective positions.
